(19) United States
(12) Patent Application Publication
(10) Pub. No.: US 2014/0374827 A1
(43) Pub. Date: Dec. 25, 2014

(54) SEMICONDUCTOR DEVICE AND METHOD FOR FABRICATING THE SAME

(71) Applicant: Samsung Electronics Co., Ltd., Suwon-si (KR)

(72) Inventors: Dong-Chan SUH, Yongin-si (KR); Chung-Geun KOH, Seoul (KR); Seong-Hoon JEONG, Seongnam-si (KR); Kwan-Heum LEE, Suwon-si (KR); Hwa-Sung RHEE, Seongnam-si (KR); Gyeom KIM, Hwaseong-si (KR)

(73) Assignee: Samsung Electronics Co., Ltd., Suwon-si (KR)

(21) Appl. No.: 14/259,212

(22) Filed: Apr. 23, 2014

(30) Foreign Application Priority Data
Jun. 24, 2013 (KR) 10-2013-0072445

(51) Int. Cl. H01L 29/78; H01L 29/06

(52) U.S. Cl. CPC H01L 29/785; H01L 29/0692
USPC 257/347

(57) ABSTRACT

A semiconductor device includes a fin type active pattern protruding above a device isolation layer, a gate electrode on the device isolation layer and intersecting the fin type active pattern, an elevated source/drain on the fin type active pattern at both sides of the gate electrode, and a fin spacer on a side wall of the fin type active pattern, the fin spacer having a low dielectric constant and being between the device isolation layer and the elevated source/drain.

### CROSS-REFERENCE TO RELATED APPLICATION

Korean Patent Application No. 10-2013-0072445, filed on Jun. 24, 2013, in the Korean Intellectual Property Office, and entitled: “Semiconductor Device And Method For Fabricating The Same,” is incorporated by reference herein in its entirety.

### BACKGROUND

1. Field

Embodiments relate to a semiconductor device and a method for fabricating the same.

2. Description of the Related Art

As one of scaling technologies which increase a density of a semiconductor device, a multi-gate transistor, in which a fin type silicon body is formed on a substrate and a gate is formed on a surface of the silicon body, has been suggested. Such multi-gate transistor uses a three-dimensional channel so that scaling is easily performed. Further, without increasing a gate length of the multi-gate transistor, a current control capacity may be improved. Furthermore, a SCE (short channel effect), i.e., a potential in the channel region affected by a drain voltage, may be efficiently suppressed.

### SUMMARY

An embodiment provides a semiconductor device in which a gate spacer is formed by a material having a low dielectric constant in a fin structure so that a capacitive coupling phenomenon between a gate and a source and/or a drain is reduced.

Another embodiment provides a semiconductor device in which a fin spacer is formed between the source/drain and a device isolation layer in the fin structure to improve a characteristic of the device.

Yet another embodiment provides a method for fabricating a semiconductor device.

In one aspect of the embodiments, there is provided a semiconductor device, including a fin type active pattern protruding above a device isolation layer, a gate electrode on the device isolation layer and intersecting the fin type active pattern, an elevated source/drain on the fin type active pattern at both sides of the gate electrode, and a fin spacer on a side wall of the fin type active pattern, the fin spacer having a low dielectric constant and being between the device isolation layer and the elevated source/drain.

A height from the device isolation layer to a bottom of the elevated source/drain may be substantially equal to a height of the fin spacer.

A dielectric constant of the fin spacer may be about 4 to about 6.

The fin spacer may include a SiOCN film.

The fin spacer may be a double layer including a SiCN film and one of a SiOCN film, a SiON film, and a silicon oxide film.

The semiconductor device may further include a gate spacer on a side wall of the gate electrode, the gate spacer having a low dielectric constant.

The fin spacer and the gate spacer may be at a same level.

The semiconductor device may further include a blocking film on the elevated source/drain, the blocking film having a low dielectric constant.

The blocking film may extend to a side wall of the gate spacer.

The semiconductor device may further include a contact on the elevated source/drain, the contact passing through the blocking film to be electrically connected to the elevated source/drain.

The elevated source/drain may have at least one of a diamond shape, a circular shape, and a rectangular shape.

In another aspect of the embodiments, there is provided a semiconductor device, including a fin type active pattern protruding above a device isolation layer, a gate electrode on the device isolation layer and intersecting the fin type active pattern, a gate spacer on a side wall of the gate electrode, the gate spacer having a low dielectric constant, an elevated source/drain on the fin type active pattern at both sides of the gate spacer, and a fin spacer on a side wall of the fin type active pattern between the device isolation layer and the elevated source/drain, the fin spacer having a dielectric constant which is equal to a dielectric constant of the gate spacer.

A dielectric constant of the gate spacer may be about 4 to about 6, the gate spacer being a single layer of a SiOCN film or a double layer including a SiCN film and one of a SiOCN film, a SiON film, and a silicon oxide film.

The semiconductor device may further include a blocking film at a side wall of the gate spacer and on the elevated source/drain, the blocking film having a low dielectric constant and including an etching resistant material.

The gate spacer and the fin spacer may be at a same level.

In yet another aspect of the embodiments, there is provided a semiconductor device, including a fin type active pattern protruding above a device isolation layer, a gate electrode on the device isolation layer and intersecting the fin type active pattern, an elevated source/drain on the fin type active pattern at both sides of the gate electrode, and a fin spacer extending along a protruding side wall of the fin type active pattern and separating between the device isolation layer and the elevated source/drain, the fin spacer having a low dielectric constant.

The semiconductor device may further include a gate spacer on the gate electrode, the gate spacer and the fin spacer being integral with each other.

The gate spacer may completely separate the elevated source/drain from the gate electrode.

The gate spacer and the fin spacer may include a same material with a dielectric constant of about 4 to about 6.

A longitudinal direction of the fin spacer may parallel a longitudinal direction of the fin type active pattern, the fin spacer covering an entire sidewall of the fin type active pattern exposed outside the gate electrode and above the device isolation layer.

### BRIEF DESCRIPTION OF THE DRAWINGS

Features will become apparent to those of ordinary skill in the art by describing in detail exemplary embodiments with reference to the attached drawings, in which:

FIG. 1 illustrates a perspective view of a semiconductor device according to an embodiment;

FIGS. 2 to 4 illustrate cross-sectional views taken along lines A-A, B-B, and C-C of FIG. 1, respectively;

FIG. 5 illustrates a perspective view of a semiconductor device according to another embodiment;

FIGS. 6 and 7 illustrate cross-sectional views taken along lines D-D and E-E of FIG. 5, respectively;

FIG. 8 illustrates a block diagram of an electronic system including a semiconductor device according to embodiments;

FIGS. 9 and 10 illustrate diagrams of examples of a semiconductor system to which a semiconductor device according to embodiments may be applied; and

FIGS. 11 to 23 illustrate diagrams of intermediate processes of a method for fabricating a semiconductor device according to an embodiment.

### DETAILED DESCRIPTION

Advantages and features of embodiments may be understood more readily by reference to the following detailed description of preferred embodiments and the accompanying drawings. Embodiments may, however, be embodied in many different forms and should not be construed as being limited to those set forth herein. Rather, these embodiments are provided so that this disclosure will be thorough and complete and will fully convey exemplary implementations of embodiments to those skilled in the art, so embodiments will only be defined by the appended claims. Like reference numerals refer to like elements throughout the specification.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being “on”, “connected to” or “coupled to” another element or layer, it can be directly on, connected or coupled to the other element or layer, or intervening elements or layers may be present. In contrast, when an element is referred to as being “directly on”, “directly connected to” or “directly coupled to” another element or layer, there are no intervening elements or layers present. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the embodiments.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Embodiments are described herein with reference to cross-section illustrations that are schematic illustrations of idealized embodiments (and intermediate structures). As such, variations from the shapes of the illustrations as a result, for example, of manufacturing techniques and/or tolerances, are to be expected. Thus, these embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the embodiments.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and this specification and will not be interpreted in an idealized or overly formal sense unless expressly so defined herein.

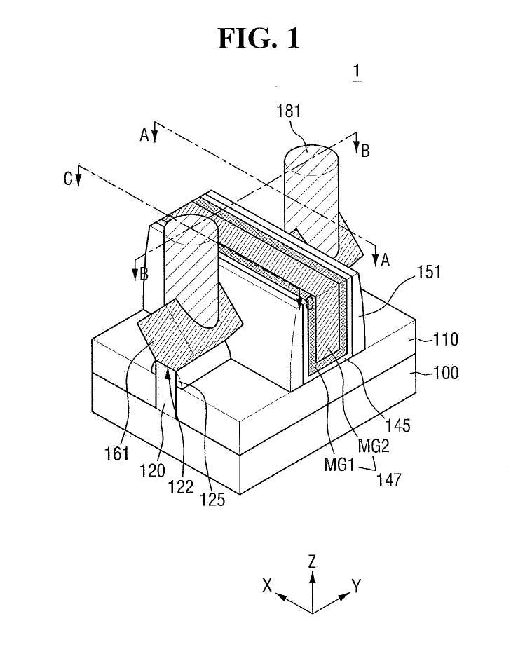

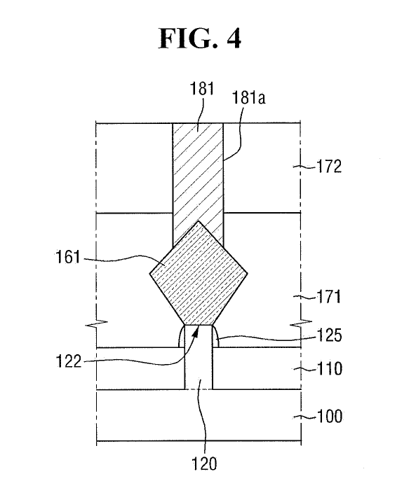

Hereinafter, a semiconductor device according to an embodiment will be described with reference to FIGS. 1 to 4.

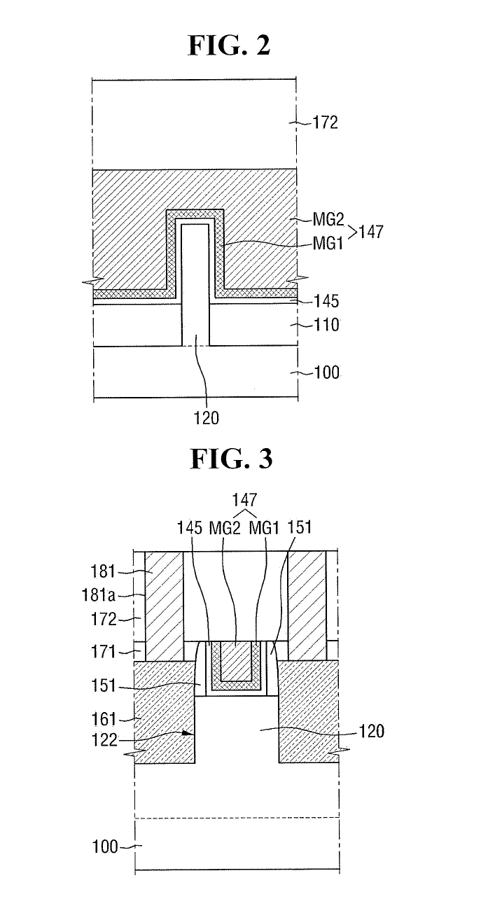

FIG. 1 illustrates a perspective view of a semiconductor device according to an embodiment, and FIGS. 2 to 4 illustrate cross-sectional views taken along lines A-A, B-B, and C-C of the semiconductor device of FIG. 1, respectively. For convenience of description, first and second interlayer insulating layers 171 and 172 are not illustrated in FIG. 1.

Referring to FIGS. 1 to 4, a semiconductor device 1 according to an embodiment may include a substrate 100, a fin type active pattern 120, a gate electrode 147, a gate spacer 151, an elevated source/drain 161, a fin spacer 125, a contact 181, a first interlayer insulating layer 171, and a second interlayer insulating layer 172.

The substrate 100 may be a bulk silicon or an SOI (silicon-on-insulator). Alternatively, the substrate 100 may be a silicon substrate or may contain other materials, e.g., silicon germanium, indium antimonide, a lead telluride compound, indium arsenic, indium phosphide, gallium arsenide, or gallium antimonide. Further, the substrate 100 may be formed such that an epitaxial layer is formed on a base substrate.

The fin type active pattern 120 may protrude from the substrate 100. A device isolation layer 110 covers a part of a side of the fin type active pattern 120 so that the fin type active pattern 120 may protrude on, e.g., above, the device isolation layer 110 which is formed on the substrate 100. For example, in the fin type active pattern 120, a portion on which the gate electrode 147 is formed and a portion on which the elevated source/drain 161 is formed protrudes onto, e.g., above, the device isolation layer 110.

The fin type active pattern 120 may be elongated along a second direction Y. The fin type active pattern 120 may be a part of the substrate 100 or may include an epitaxial layer which is grown from the substrate 100.

The gate electrode 147 may be formed on the fin type active pattern 120 so as to intersect the fin type active pattern 120. In other words, the gate electrode 147 may be formed on the device isolation layer 110. The gate electrode 147 may be extended in a first direction X.

The gate electrode 147 may include metal layers MG1 and MG2. As illustrated in the drawing, the gate electrode 147 may be formed of two or more metal layers MG1 and MG2 laminated thereon. The first metal layer MG1 controls a work function and the second metal layer MG2 fills a space formed by the first metal layer MG1. For example, the first metal layer MG1 may include at least one of TiN, TaN, TiC, and TaC. Further, the second metal layer MG2 may include W or Al. Alternatively, the gate electrode 147 may be formed of Si or SiGe rather than a metal. Such a gate electrode 147 may be formed by a replacement process, but is not limited thereto.

A gate insulating layer 145 may be formed between the fin type active pattern 120 and the gate electrode 147. The gate insulating layer 145 may be formed above a top surface and a side surface of the fin type active pattern 120. Further, the gate insulating layer 145 may be disposed between the gate electrode 147 and the device isolation layer 110. The gate insulating layer 145 may include a high dielectric material having a higher dielectric constant than that of a silicon oxide layer. For example, the gate insulating layer 145 may include at least one of hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, but is not limited thereto.

The gate spacer 151 may be formed on a side wall of the gate electrode 147 which extends in the first direction X, i.e., a side wall of the gate insulating layer 145. Even though the gate spacer 151 is a single layer in the drawing, the gate spacer 151 is not limited thereto but may have a double layered structure.

The gate spacer 151 has a low dielectric constant. Here, “the gate spacer having a low dielectric constant” means that when the gate spacer 151 is a single layer, a dielectric constant of a dielectric material of the gate spacer 151 is low. Further, it means that when the gate spacer 151 is a double layer, a total of the dielectric constants of the dielectric materials of the gate spacer 151 is low.

For example, the gate spacer 151 may be a single layer which is formed of an SiOCN film. Further, the gate spacer 151 may be a double layer which includes a SiCN film and one selected from a SiOCN film, a SiON film, and a silicon oxide film. When the gate spacer 151 has a double layered structure, one selected from the SiOCN film, the SiON film, and the silicon oxide film may be formed at an inner side of the gate spacer 151 so as to be adjacent to the gate electrode 147, and the SiCN film may be formed at an outer side, but embodiments are not limited thereto. For example, the dielectric constant of the gate spacer 151 may have a value of 4 or larger and 6 or smaller.

The gate spacer 151 may be formed of an etching resistant material. For example, the gate spacer 151 has an etch rate which is similar to that of the silicon nitride but has a dielectric constant which is lower than that of the silicon nitride. When the gate spacer 151 is formed of a material having a low dielectric constant, a capacitive coupling between the gate electrode 147 and the elevated source/drain 161 may be reduced. When the capacitive coupling is reduced, an AC performance of the semiconductor device 1 may be improved.

The elevated source/drain 161 may be formed on the fin type active pattern 120 at both sides of the gate electrode 147. At another aspect, the elevated source/drain 161 may be formed in a recess 122 formed in the fin type active pattern 120.

The fin type active pattern 120, which does not cover the gate electrode 147, protrudes onto, e.g., above, the device isolation layer 110 so that the elevated source/drain 161 may be spaced apart from the device isolation layer 110. That is, the elevated source/drain 161 may be spaced apart from the device isolation layer 110 as much as a height of the fin type active pattern 120, which protrudes onto the device isolation layer 110.

In the meantime, the elevated source/drain 161 may have various shapes. For example, the elevated source/drain 161 may have at least one of, e.g., a diamond shape, a circular shape, and a rectangular shape. In FIGS. 1 to 4, the elevated source/drain 161 is illustrated to have a diamond shape (or pentagonal shape or hexagonal shape).

When the semiconductor device 1 is a PMOS fin type transistor, the source/drain 161 may include a compressive stress material. For example, the compressive stress material may be a material which has a larger lattice constant than Si, e.g., SiGe. The compressive stress material applies a compressive stress to the fin type active pattern 120 to improve a mobility of a carrier of a channel region.

In contrast, when the semiconductor device 1 is an NMOS fin type transistor, the source/drain 161 may be formed of the same material as the substrate 100 or of a tensile stress material. For example, when the substrate 100 is Si, the source/drain 161 may be Si or a material which has a lower lattice constant than Si, e.g., SiC).

The fin spacer 125 may be formed between the device isolation layer 110 and the elevated source/drain 161. The fin spacer 125 may be formed on, e.g., directly on, a side wall of the fin type active pattern 120 which protrudes onto the device isolation layer 110. In the drawings, the fin spacer 125 is a single layer, but the fin spacer 125 is not limited thereto, and may have a double layered structure.

The fin spacer 125 is physically connected with the gate spacer 151, e.g., the fin spacer 125 may be in direct contact with the gate spacer 151. The fin spacer 125 is formed at both sides of the gate electrode 147 and the gate spacer 151, and may extend in the second direction Y.

In the semiconductor device according to embodiments, a height of the fin spacer 125 may be substantially equal to a height to the bottom portion of the source/drain 161 elevated from the device isolation layer 110. In other words, the fin spacer 125 may extend along an entire distance between the device isolation layer 110 and a bottom of the source/drain 161, e.g., the height of the fin spacer 125 along a normal to the device isolation layer 110 may equal a height of an upper portion of the fin type active pattern 120 protruding above the device isolation layer 110.

The fin spacer 125 has a low dielectric constant. Here, “the fin spacer having a low dielectric constant” means that when the fin spacer 125 is a single layer, a dielectric constant of a dielectric material of the fin spacer 125 is low. Further, it means that when the fin spacer 125 is a double layer, a total of the dielectric constants of the dielectric materials of the fin spacer 125 is low.

In the semiconductor device according to embodiments, the dielectric constant of the fin spacer 125 may have a value of 4 or larger and 6 or smaller, e.g., the dielectric constant of the fin spacer 125 may be between 4 and 6. For example, the fin spacer 125 may be a single layer formed of SiOCN film. In another example, the fin spacer 125 may be a double layer including a SiCN film and at least one of a SiOCN film, a SiON film, and a silicon oxide film. The fin spacer 125 may be formed of an etching resistant material. For example, the fin spacer 125 has an etch rate which is similar to that of the silicon nitride but has a dielectric constant which is lower than that of the silicon nitride

The fin spacer 125 may be formed at the same level as the gate spacer 151. Here, the “same level” means that the spacers are formed by the same fabricating process. Further, the fin spacer 125 and the gate spacer 151 may be a single, e.g., same, layer formed of the same material or a double layer formed by laminating the same materials into a single and uniform structure, so that the dielectric constants of the fin spacer 125 and the gate spacer 151 may be substantially same. Here, the “same dielectric constant” means that the dielectric constants of the two layers which are compared with each other are the same and that the two layers have a minute difference of the dielectric constants which may be caused by a margin during the process.

The contact 181 electrically connects wiring lines and the elevated source/drain 161. The contact 181 may include Al, Cu, and W, but is not limited thereto. The contact 181 may be formed by filling a contact hole 181a which is formed to pass through the first interlayer insulating layer 171 and a second interlayer insulating layer 172 with a conductive material, but is not limited thereto.

For example, as illustrated in FIG. 3, a top surface of the first interlayer insulating layer 171 may be even, e.g., coplanar, with a top surface of the gate electrode 147. The top surfaces of the first interlayer insulating layer 171 and the first gate electrode 147 may be even by a planarizing process, e.g., a CMP process. The second interlayer insulating layer 172 may be formed to cover the first interlayer insulating layer 171 and the gate electrode 147.

The first interlayer insulating layer 171 and the second interlayer insulating layer 172 may include at least one of a material having a low dielectric constant, an oxide film, a nitride film, and an oxynitride film. Examples of the material having a low dielectric constant may include FOX (flowable oxide), TOSZ (tonen silazene), USG (undoped silica glass), BSG (borosilica glass), PSG (phosphosilica glass), BPSG (borophosphosilica glass), PRTEOS (plasma enhanced tetra ethyl ortho silicate), FSG (fluoride silicate glass), HDP (high density plasma), PEOX (plasma enhanced oxide), FCVD (flowable CVD) and a combination thereof.

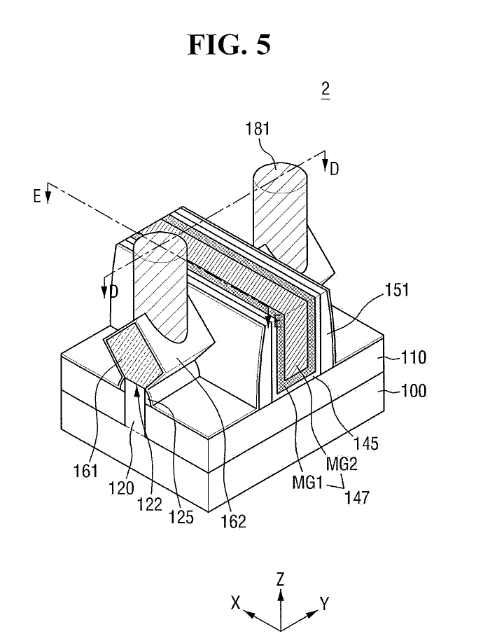

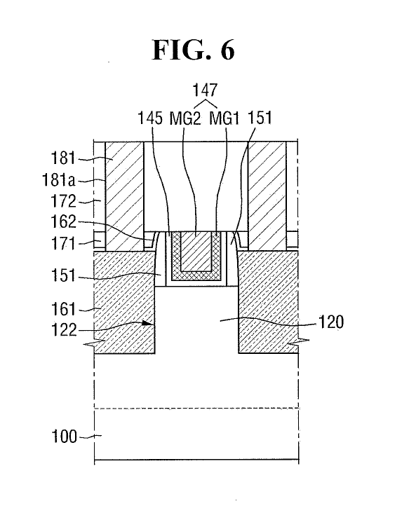

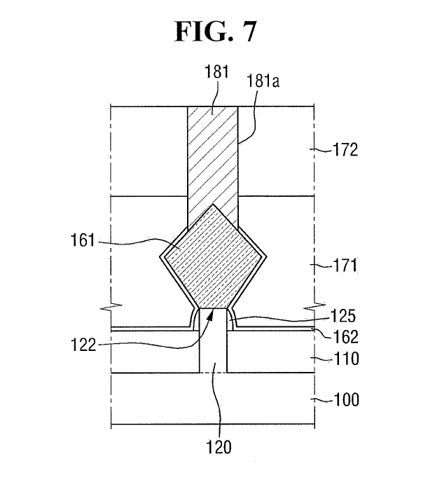

A semiconductor device according to another embodiment will be described with reference to FIGS. 5 to 7. FIGS. 6 and 7 illustrate cross-sectional views taken along lines D-D and E-E of the semiconductor device of FIG. 5, respectively. For convenience of description, different portions relative to the description of FIGS. 1 to 4 will be mainly described.

Referring to FIGS. 5 to 7, a semiconductor device 2 according to another embodiment may include the substrate 100, the fin type active pattern 120, the gate electrode 147, the gate spacer 151, the elevated source/drain 161, the fin spacer 125, a blocking film 162, the contact 181, the first interlayer insulating layer 171, and the second interlayer insulating layer 172.

The blocking film 162 is formed on, e.g., directly on, the elevated source/drain 161. The blocking film 162 is formed on the device isolation layer 110, the fin spacer 125, the elevated source/drain 161, and the gate spacer 151.

The blocking film 162 may be conformally formed on the elevated source/drain 161, the fin spacer 125, and the device isolation layer 110. The blocking film 162 includes an opening which is formed in a region where the contact 181 and the elevated source/drain 161 are electrically connected. The blocking film 162 may serve as an etch stop layer during a process of forming the contact 181 on the elevated source/drain 161.

The blocking film 162 may include an etching resistant material. Further, the blocking film 162 may have a low dielectric constant, but is not limited thereto. For example, the blocking film 162 may be a single layer which is formed of a SiOCN film or a SiN film. Further, the blocking film 162 may be a double layer which includes a SiCN film and one selected from a SiOCN film, a SiON film, and a silicon oxide film. The blocking film 162 may include a material which has an etching selectivity with respect to the first interlayer insulating layer 171 so as to serve as an etch stop layer during a process of forming the contact hole 181a.

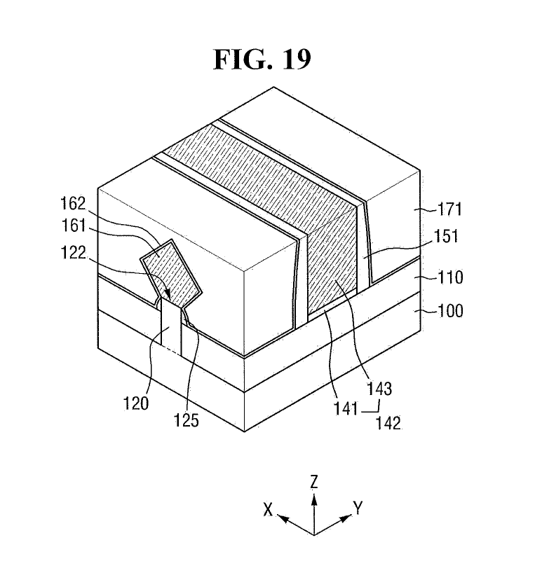

The blocking film 162 is formed not only on the elevated source/drain 161 but also extends to the side of the gate spacer 151. However, the blocking film 162 is not formed on the top surface of the gate electrode 147. This is because the gate electrode 147 is formed after removing a part of the blocking film 162 (see FIGS. 19 to 21).

The blocking film 162 is also formed at the side of the gate spacer 151 so as to serve as an additional gate spacer of the gate electrode 147. Further, in the planarizing process, e.g., the CMP process, which is performed to form the gate electrode 147, the blocking film 162, which is formed at the side of the gate spacer 151, supports the gate spacer 151 so as not to deform a shape of the upper portion of the gate spacer 151.

The contact 181 which is formed on the elevated source/drain 161 passes through the blocking film 162 which is formed on the elevated source/drain 161 to be electrically connected with the elevated source/drain 161.

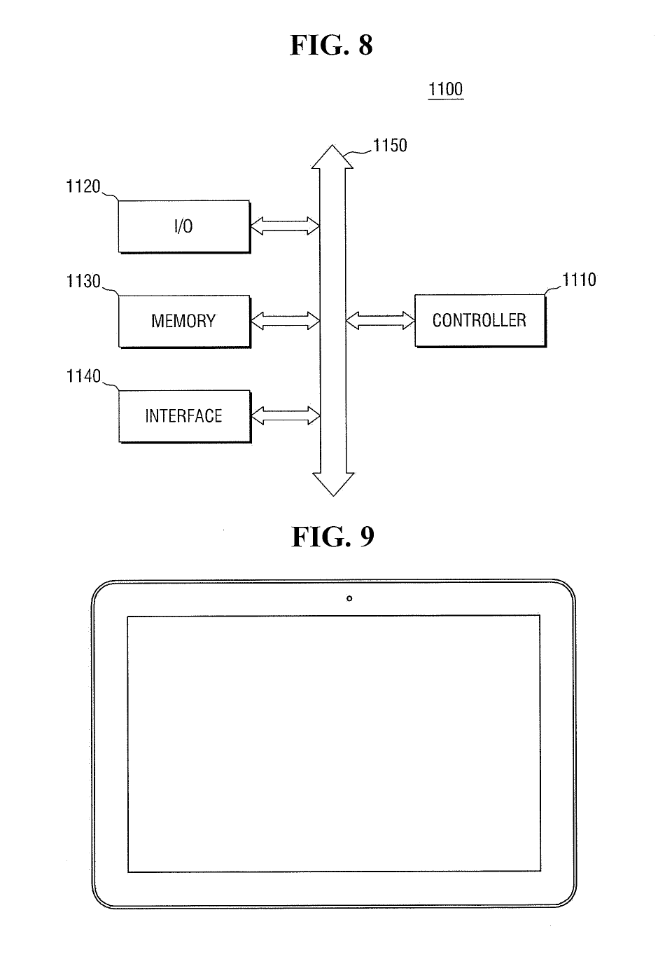

Next, an example of an electronic system, which uses the semiconductor device of FIGS. 1 to 7 will be described with reference to FIG. 8. FIG. 8 illustrates a block diagram of an electronic system including a semiconductor device according to embodiments.

Referring to FIG. 8, an electronic system 1100 according to an embodiment may include a controller 1110, an input/output device (I/O) 1120, a memory device 1130, an interface 1140, and a bus 1150. The controller 1110, the input/output device 1120, the memory device 1130, and/or the interface 1140 may be coupled to each other through the bus 1150. The bus 1150 corresponds to a path through which data moves.

The controller 1110 may include at least one of, e.g., a microprocessor, a digital signal processor, a micro controller, and logical devices which perform a similar function to the microprocessor, the digital signal processor, and the micro controller. The input/output device 1120 may include, e.g., a keypad, a keyboard, and a display device. The memory device 1130 may store data and/or command languages. The interface 1140 may perform a function which transmits data to a communication network or receives data from the communication network. The interface 1140 may be a wired or wireless type. For example, the interface 1140 may include an antenna or a wired or wireless transceiver. Even though not illustrated, the electronic system 1100 may further include a high speed DRAM and/or SRAM as an operating memory which improves an operation of the controller 1110. The semiconductor device according to embodiments may be provided in the memory device 1130 or provided as a part of the controller 1110 or the input/output device (I/O) 1120.

The electronic system 1100 may be applied to, e.g., a PDA (personal digital assistant), a portable computer, a web tablet, a wireless phone, a mobile phone, a digital music player, a memory card or any of electronic products which transmit and/or receive information in a wireless environment.

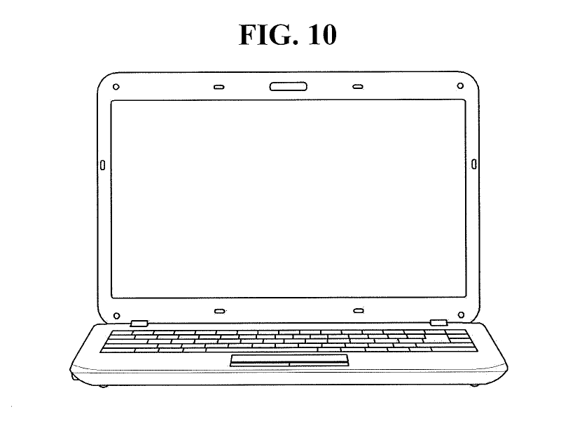

FIGS. 9 and 10 illustrate diagrams of examples of a semiconductor system to which the semiconductor device according to the several embodiments may be applied. FIG. 9 illustrates a tablet PC and FIG. 10 illustrates a notebook computer. At least one of the semiconductor devices according to several embodiments may be used for the tablet PC and the notebook computer. Further, the semiconductor devices according to several embodiments may be applied to other integrated circuit devices which have not been exemplified.

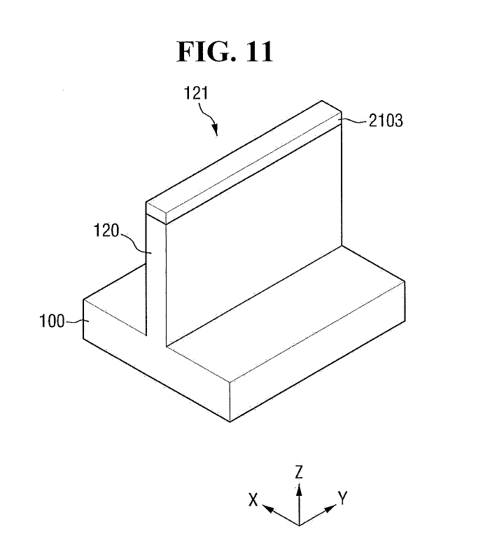

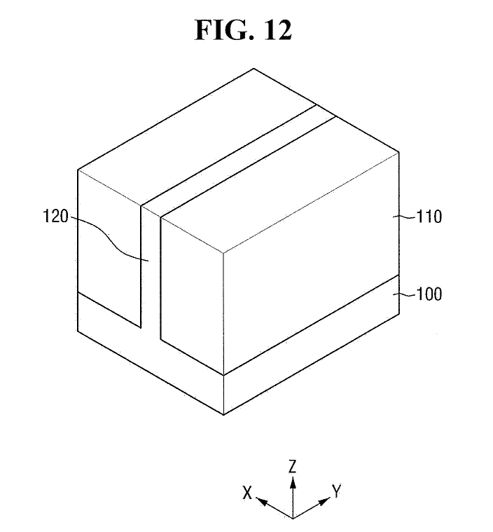

A method for fabricating a semiconductor device according to an embodiment will be described with reference to FIGS. 11 to 24. The semiconductor device which is formed by the processes of FIGS. 11 to 23 is the semiconductor device which has been described with reference to FIGS. 5 to 7.

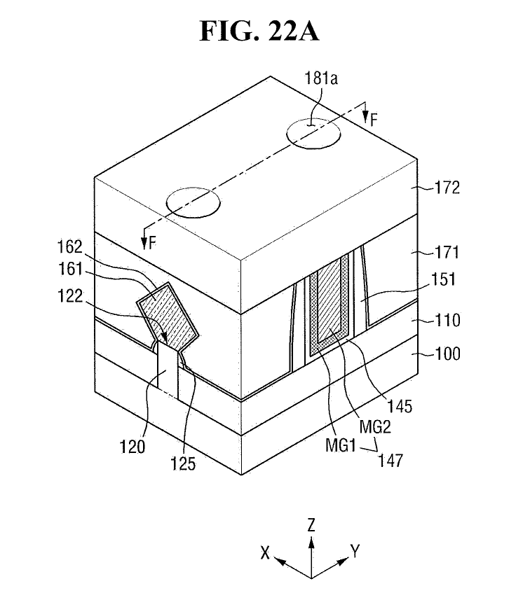

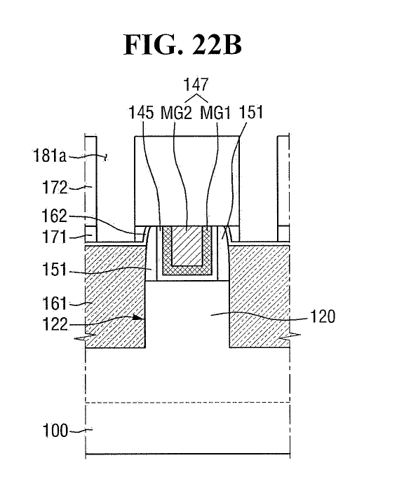

FIGS. 11 to 23 illustrate diagrams of intermediate processes of a method for fabricating a semiconductor device according to an embodiment. FIG. 22B illustrates a cross-sectional view taken along line F-F of FIG. 22A.

Referring to FIG. 11, the fin type active pattern 120 is formed on the substrate 100. For example, after forming a mask pattern 2103 on the substrate 100, an etching process is performed to form the fin type active pattern 120. The fin type active pattern 120 may extend along the second direction Y. A trench 121 is formed around the fin type active pattern 120. The mask pattern 2103 may be formed of a material including at least one of, e.g., a silicon oxide film, a silicon nitride film, and a silicon oxynitride film.

Referring to FIG. 12, a device isolation layer 110 is formed to fill the trench 121. The device isolation layer 110 may be formed of a material including at least one of a silicon oxide film, a silicon nitride film, and a silicon oxynitride film.

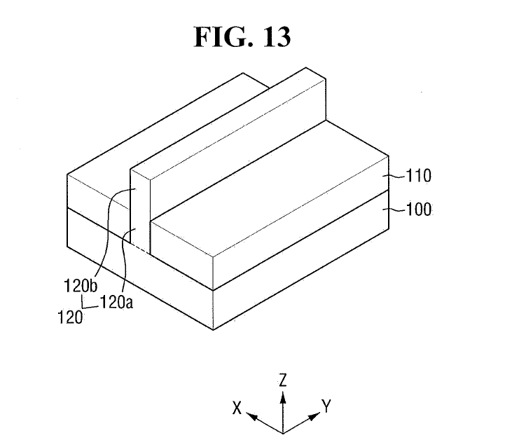

By a planarizing process, the fin type active pattern 120 and the device isolation layer 110 may be disposed on the same plane. The mask pattern 2103 may be removed while performing the planarizing process, but embodiments are not limited thereto. In other words, the mask pattern 2103 may be removed before forming the device isolation layer 110 or after performing a recess process which will be described with reference to FIG. 13.

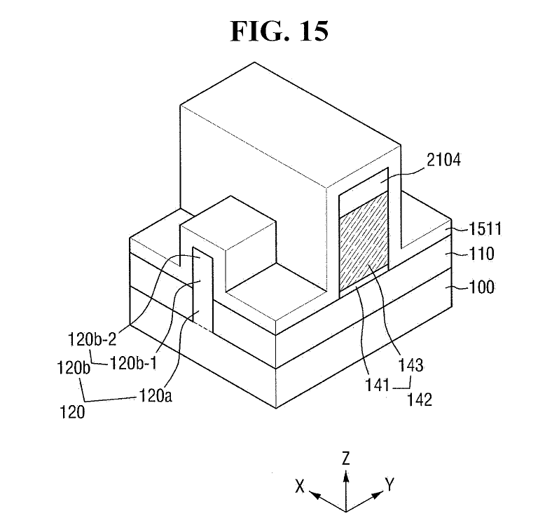

Referring to FIG. 13, an upper portion of the device isolation layer 110 is recessed to expose a part, e.g., an upper part, of the fin type active pattern 120. The recess process may include a selective etching process. That is, the fin type active pattern 120 is formed so as to protrude onto, e.g., above, an upper surface of the recessed device isolation layer 110. In other words, a lower portion 120a of the fin type active pattern is on the substrate 100 and in contact with the device isolation layer 110 so as to be enclosed by the device isolation layer 110, but an upper portion 120b of the fin type active pattern 120 is not in contact with the device isolation layer 110 so as to protrude above the device isolation layer 110. Referring to FIG. 15 which will be described below, the upper portion 120b of the fin type active pattern 120 includes a first portion 120b-1 and a second portion 120b-2.

Further, the part of the fin type active pattern 120 which protrudes onto the device isolation layer 110 may be formed by an epitaxial process. For example, after forming the device isolation layer 110, a part of the fin type active pattern 120 may be formed by the epitaxial process, which uses the upper surface of the fin type active pattern 120 exposed by the device isolation layer 110 as a seed without performing the recess process.

Further, a doping process for controlling a threshold voltage may be performed on the fin type active pattern 120. When the semiconductor devices 1 and 2 are NMOS fin type transistors, the impurity may be boron (B). When the semiconductor devices 1 and 2 are PMOS fin type transistors, the impurity may be phosphorus (P) or arsenic (As).

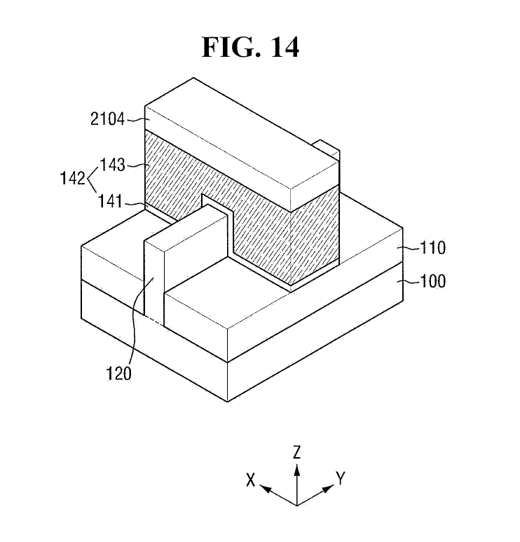

Referring to FIG. 14, an etching process is performed using a mask pattern 2104 to form a dummy gate pattern 142, which extends in a first direction X so as to intersect the fin type active pattern 120. By doing this, the dummy gate pattern 142 is formed on the fin type active pattern 120. The dummy age pattern 142 may overlap a part of the fin type active pattern 120 on the device isolation layer 110. The fin type active pattern 120 includes a portion which is covered by the dummy gate pattern 142 and a portion which is exposed by the dummy gate pattern 142.

The dummy gate pattern 142 includes a dummy gate insulating layer 141 and a dummy gate electrode 143. For example, the dummy gate insulating layer 141 may be a silicon oxide film and the dummy gate electrode 143 may be polysilicon.

In the method for fabricating a semiconductor device according to the present embodiment, the dummy gate pattern 142 is formed so as to form a replacement gate electrode, but embodiments are not limited thereto. For example, the gate pattern may be formed using a material which is used for a gate insulating layer and the gate electrode of the transistor, not the dummy gate pattern.

Referring to FIG. 15, a spacer film 1511 which covers the dummy gate pattern 142 and the fin type active pattern 120 is formed on the device isolation layer 110. The spacer film 1511 may be conformally formed on the dummy gate pattern 142 and the fin type active pattern 120. The spacer film 1511 is formed on the upper portion 120b of the fin type active pattern 120 which protrudes onto the device isolation layer 110.

The spacer film 1511 has a low dielectric constant. For example, the spacer film 1511 may be a single layer which is formed of a SiOCN film. In another example, the spacer film 1511 may be a double layer which includes a SiCN film and one of a SiOCN film, a SiON film, and a silicon oxide film. The spacer film 1511 may be formed using a chemical vapor deposition method (CVD) or an atomic layer deposition method (ALD).

In the method for fabricating a semiconductor device according to the present embodiment, the dielectric constant of the spacer film 1511 may have a value of 4 or larger and 6 or smaller. The spacer film 1511 may be formed of an etching resistant material. For example, the spacer film 1511 may have an etch rate which is similar to that of the silicon nitride but has a dielectric constant which is lower than that of the silicon nitride

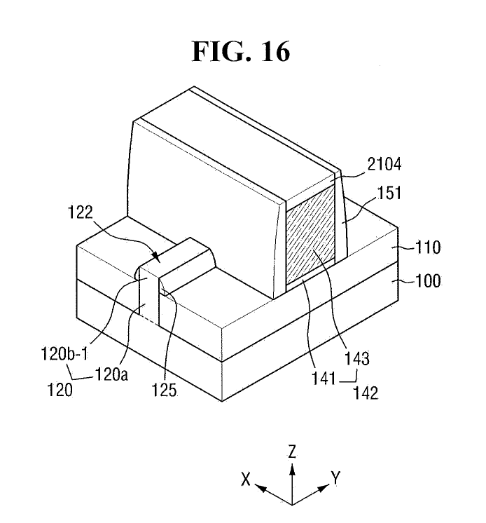

Referring to FIG. 16, a part of the upper portion 120b of the fin type active pattern 120 which protrudes above the device isolation layer 110 is etched to form recesses 122 at both sides of the dummy gate pattern 142. For example, the second portion 120b-2 of the upper portion 120b of the fin type active pattern 120 (in FIG. 15) is etched, e.g., removed, to form the recess 122 in the fin type active pattern 120.

By the etching process which forms the recess 122, the fin spacer 125 is formed on a side wall of the first portion 120b-1 of the upper portion 120b of the fin type active pattern 120, and the gate spacer 151 is formed on a side wall of the dummy gate pattern 142. An etching selectivity of the material included in the fin type active pattern 120 and the material included in the spacer film 1511 is adjusted so that a height from the upper surface of the device isolation film 110 to the bottom surface of the recess 122 and a height of the fin spacer 125 are substantially equal to each other.

In the method for fabricating a semiconductor device according to embodiments, the recess 122, the gate spacer 151, and the fin spacer 125 may be formed simultaneously. The fin spacer 125 and the gate spacer 151 are structures formed from the spacer film 1511, so that the fin spacer 125 and the gate spacer 151 have a low dielectric constant like the spacer film 1511.

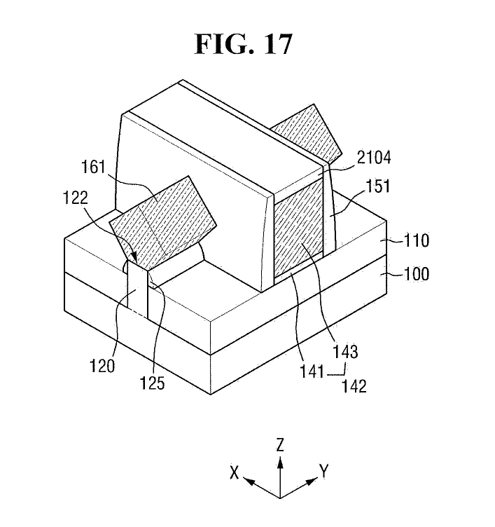

Referring to FIG. 17, the elevated source/drain 161 is formed in the recess 122. That is, the elevated source/drain 161 is formed on the fin type active pattern 120, in other word, on the first portion 120b-1 of the upper portion of the fin type active pattern.

The elevated source/drain 161 may be formed by an epitaxial process. A material for the elevated source/drain 161 may vary depending on whether the semiconductor devices 1 and 2 according to embodiments are n type transistors or p type transistors. Further, if necessary, an impurity may be doped in situ during the epitaxial process.

The elevated source/drain 161 may have at least one of a diamond shape, a circular shape, and a rectangular shape. In FIG. 17, the elevated source/drain 161 is illustrated to have a diamond shape (or pentagonal shape or hexagonal shape) as an example.

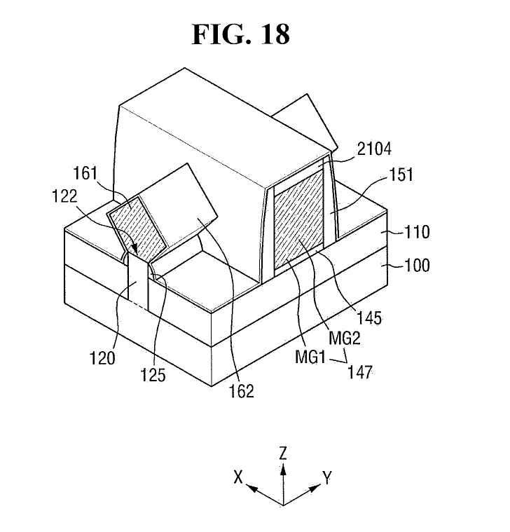

Referring to FIG. 18, the blocking film 162 which covers the elevated source/drain 161, the gate spacer 151, the fin spacer 125, and the dummy gate pattern 142 is conformally formed. The blocking film 162 may be a single layer which is formed of a SiOCN film or an SiN film, or the blocking film 162 may be a double layer which includes a SiCN film and one of a SiOCN film, a SiON film, and a silicon oxide film. The blocking film 162 has a low dielectric constant and may include an etching resistant material. The blocking film 162 may be formed using a chemical vapor deposition method (CVD) or an atomic layer deposition method (ALD)

Referring to FIG. 19, the first interlayer insulating layer 171 is formed on the elevated source/drain which is covered by the blocking film 162. The first interlayer insulating layer 171 may include at least one of a material having a low dielectric constant, an oxide film, a nitride film, and an oxynitride film.

Next, the first interlayer insulating layer 171 is planarized until the top surface of the dummy gate pattern 142 is exposed. As a result, a mask pattern 2104 is removed from the top surface of the dummy gate pattern 142.

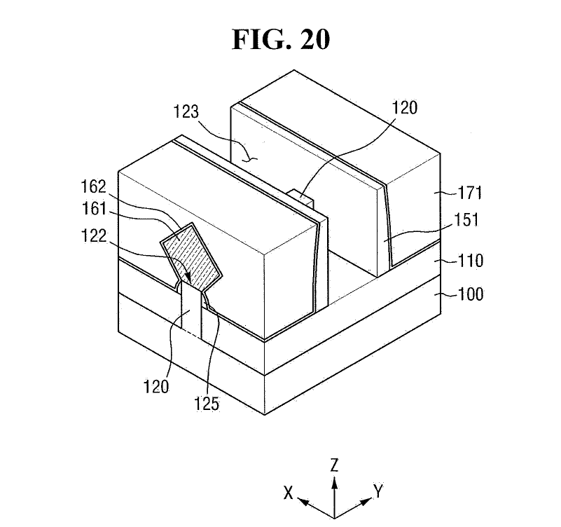

Referring to FIG. 20, the dummy gate pattern 142, i.e., the dummy gate insulating layer 141 and the dummy gate electrode 143, is removed. By removing the dummy gate insulating layer 141 and the dummy gate electrode 143, a trench 123 which exposes a part of the device isolation layer 110 and the fin type active pattern 120, is formed.

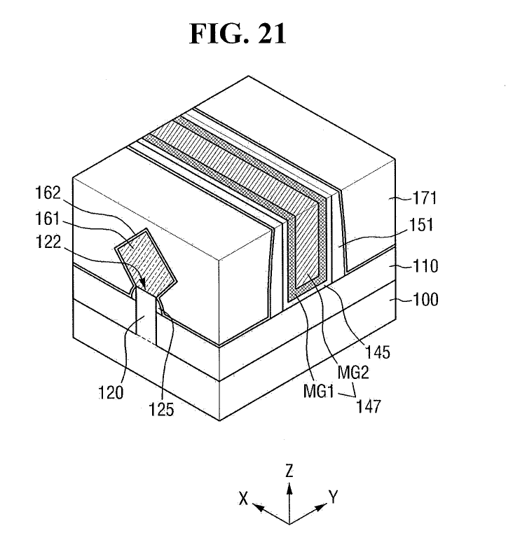

Referring to FIG. 21, the gate insulating layer 145 and the gate electrode 147 are formed in the trench 123. The gate insulating layer 145 may include a high dielectric material having a higher dielectric material than the silicon oxide film. The gate insulating layer 145 may be substantially conformally formed along the side wall and the bottom surface of the trench 123. The gate electrode 147 may include the metal layers MG1 and MG2. As illustrated in the drawing, the gate electrode 147 may be formed by two or more metal layers MG1 and MG2 laminated thereon. The first metal layer MG1 controls a work function and the second metal layer MG2 fills a space formed by the first metal layer MG1. For example, the first metal layer MG1 may include at least one of TiN, TaN, TiC, and TaC. Further, the second metal layer MG2 may include W or Al. Alternatively, the gate electrode 147 may be formed of Si or SiGe rather than a metal

Referring to FIGS. 22A and 22B, the second interlayer insulating layer 172 is formed on the first interlayer insulating layer 171 and the gate electrode 147. The second interlayer insulating layer 172 may include at least one of a material having a low dielectric constant, an oxide film, a nitride film, and an oxynitride film.

Next, a contact hole 181a is formed to pass through the first interlayer insulating layer 171 and the second interlayer insulating layer 172. Since the first interlayer insulating layer 171 and the blocking film 162 having an etching selectivity are formed on the elevated source/drain 161, the contact hole 181a does not expose the elevated source/drain 161. In other words, the blocking film 162 which has a low dielectric constant serves as an etch stop layer when the contact hole 181a is formed.

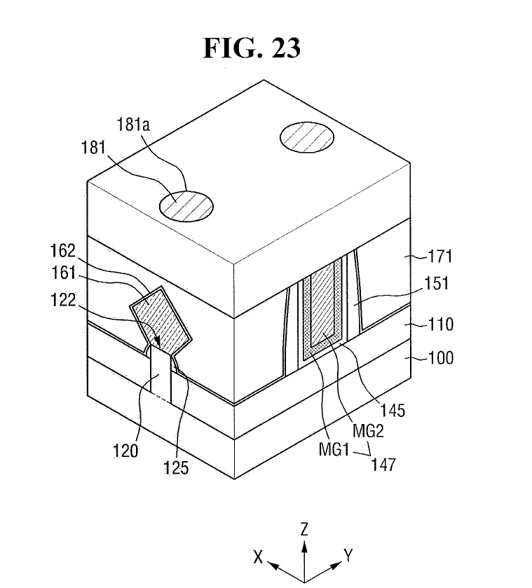

Referring to FIGS. 23 and 6, the blocking film 162 which is exposed by the contact hole 181a is removed to expose the elevated source/drain 161. The contact hole 181a is filled with a conductive material to form a contact 181 on the exposed elevated source/drain 161. The elevated source/drain 161 and the contact 181 are electrically connected to each other. The contact 181 passes through the first interlayer insulating layer 171, the second interlayer insulating layer 172, and the blocking film 162 to be formed on the elevated source/drain 161.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor device, comprising:
a fin type active pattern protruding above a device isolation layer;
a gate electrode on the device isolation layer and intersecting the fin type active pattern;
an elevated source/drain on the fin type active pattern at both sides of the gate electrode; and
a fin spacer on a side wall of the fin type active pattern, the fin spacer having a low dielectric constant and being between the device isolation layer and the elevated source/drain.

2. The semiconductor device as claimed in claim 1, wherein a height from the device isolation layer to a bottom of the elevated source/drain is substantially equal to a height of the fin spacer.

3. The semiconductor device as claimed in claim 1, wherein a dielectric constant of the fin spacer is about 4 to about 6.

4. The semiconductor device as claimed in claim 3, wherein the fin spacer includes a SiOCN film.

5. The semiconductor device as claimed in claim 3, wherein the fin spacer is a double layer including a SiCN film and one of a SiOCN film, a SiON film, and a silicon oxide film.

6. The semiconductor device as claimed in claim 1, further comprising a gate spacer on a side wall of the gate electrode, the gate spacer having a low dielectric constant.

7. The semiconductor device as claimed in claim 6, wherein the fin spacer and the gate spacer are at a same level.

8. The semiconductor device as claimed in claim 6, further comprising a blocking film on the elevated source/drain, the blocking film having a low dielectric constant.

9. The semiconductor device as claimed in claim 8, wherein the blocking film extends to a side wall of the gate spacer.

10. The semiconductor device as claimed in claim 8, further comprising a contact on the elevated source/drain, the contact passing through the blocking film to be electrically connected to the elevated source/drain.

11. The semiconductor device as claimed in claim 1, wherein the elevated source/drain has at least one of a diamond shape, a circular shape, and a rectangular shape.

12. A semiconductor device, comprising:
a fin type active pattern protruding above a device isolation layer;
a gate electrode on the device isolation layer and intersecting the fin type active pattern;
a gate spacer on a side wall of the gate electrode, the gate spacer having a low dielectric constant;
an elevated source/drain on the fin type active pattern at both sides of the gate spacer; and
a fin spacer on a side wall of the fin type active pattern between the device isolation layer and the elevated source/drain, the fin spacer having a dielectric constant which is equal to a dielectric constant of the gate spacer.

13. The semiconductor device as claimed in claim 12, wherein a dielectric constant of the gate spacer is about 4 to about 6, the gate spacer being a single layer of a SiOCN film or a double layer including a SiCN film and one of a SiOCN film, a SiON film, and a silicon oxide film.

14. The semiconductor device as claimed in claim 12, further comprising a blocking film at a side wall of the gate spacer and on the elevated source/drain, the blocking film having a low dielectric constant and including an etching resistant material.

15. The semiconductor device as claimed in claim 12, wherein the gate spacer and the fin spacer are at a same level.

16. A semiconductor device, comprising:
a fin type active pattern protruding above a device isolation layer;
a gate electrode on the device isolation layer and intersecting the fin type active pattern;
an elevated source/drain on the fin type active pattern at both sides of the gate electrode; and
a fin spacer extending along a protruding side wall of the fin type active pattern and separating between the device isolation layer and the elevated source/drain, the fin spacer having a low dielectric constant.

17. The semiconductor device as claimed in claim 16, further comprising a gate spacer on the gate electrode, the gate spacer and the fin spacer being integral with each other.

18. The semiconductor device as claimed in claim 17, wherein the gate spacer completely separates the elevated source/drain from the gate electrode.

19. The semiconductor device as claimed in claim 17, wherein the gate spacer and the fin spacer include a same material with a dielectric constant of about 4 to about 6.

20. The semiconductor device as claimed in claim 16, wherein a longitudinal direction of the fin spacer parallels a longitudinal direction of the fin type active pattern, the fin spacer covering an entire sidewall of the fin type active pattern exposed outside the gate electrode and above the device isolation layer.
